(19) United States
(12) Patent Application Publication
(10) Pub. No.: US 2017/0025643 A1
(43) Pub. Date: Jan. 26, 2017

(54) CRUCIBLE AND EVAPORATION DEVICE

(71) Applicants: BOE TECHNOLOGY GROUP CO., LTD., Beijing (CN); ORDOS YUANSHENG OPTOELECTRONICS CO., LTD., Ordos (CN)

(72) Inventor: Ruiting HE, Beijing (CN)

(73) Assignees: BOE TECHNOLOGY GROUP CO., LTD., Beijing (CN); ORDOS YUANSHENG OPTOELECTRONICS CO., LTD., Ordos (CN)

(21) Appl. No.: 15/140,206

(22) Filed: Apr. 27, 2016

(30) Foreign Application Priority Data
Jul. 23, 2015 (CN) 201510437009.3

(51) Int. Cl. H01L 51/56; H01L 51/00

(52) U.S. Cl. CPC H01L 51/56; H01L 51/001

(57) ABSTRACT

The present disclosure provides a crucible and an evaporation device. The crucible includes an external wall, an internal wall and a heating member arranged outside the external wall. The external wall and the internal wall define a cavity, and a heat transfer liquid is received in the cavity.

### CROSS-REFERENCE TO RELATED APPLICATION

The present application claims a priority of the Chinese Patent Application No. 201510437009.3 filed on Jul. 23, 2015, which is incorporated herein by reference in its entirety.

### TECHNICAL FIELD

The present disclosure relates to the field of evaporation technology, in particular to a crucible and an evaporation device.

### BACKGROUND

Recently, liquid crystal display (LCD) panels and organic light-emitting diode (OLED) panels have been widely used, and OLED is mainly used for a small-size panel. As compared with LCD, an OLED display device is a development trend for a next-generation display device due to its advantages such as being light and thin, low power consumption, high contrast, large gamut and being capable of achieving flexible display. OLED display includes passive matrix OLED (PMOLED) display and active matrix OLED (AMOLED) display, and the AMOLED display may be implemented by (1) a low temperature poly-silicon (LTPS) back plate and a fine metal mask (FMM), and (2) an oxide back plate, a white OLED (WOLED) and a color filter. The former is mainly used for a small-size panel, e.g., a mobile phone or any other mobile terminal, and the latter is mainly used for a large-size panel, e.g., a monitor or a television. The technology “LTPS back plate+FMM” has now matured, and has been used for mass production.

For an FFM mode, an OLED material is evaporated onto the LTPS back plate in a predetermined manner, and red, green and blue OLEDs are formed in accordance with patterns on the FMM. The evaporation is conducted within a vacuum cavity. During the mass production, a linear evaporation source and a linear crucible are usually adopted. However, it is impossible for a conventional crucible to heat a to-be-evaporated material uniformly, and there is no solution for this in the related art.

### SUMMARY

A main object of the present disclosure is to provide crucible and an evaporation device, so as to provide a uniform temperature, provide a resultant film with a uniform thickness and to prevent a material within the crucible from being modified.

In one aspect, the present disclosure provides in some embodiments a crucible, including an external wall, an internal wall and a heating member arranged outside the external wall. The external wall and the internal wall define a cavity, and a heat transfer liquid is received in the cavity.

Alternatively, the external wall and the internal wall are made of titanium.

Alternatively, a liquid supply pipe for supplying the heat transfer liquid into the cavity is arranged at a side wall of the external wall.

Alternatively, an inlet of the liquid supply pipe is located at a level higher than the side wall.

Alternatively, the liquid supply pipe is provided with a cooling member for cooling the liquid supply pipe, so as to enable a gaseous heat transfer material evaporated and entering the liquid supply pipe to be cooled and converted into the heat transfer liquid, and flow back into the cavity.

Alternatively, the liquid supply pipe is provided with a temperature controller for monitoring a temperature of the liquid supply pipe in real time and transmitting the temperature to the cooling member, so as to enable the cooling member to cool the liquid supply pipe in accordance with a difference between the temperature and a temperature threshold.

Alternatively, a cover for sealing the liquid supply pipe is provided at the inlet of the liquid supply pipe.

Alternatively, after the liquid supply pipe is sealed with the cover, besides the heat transfer liquid, a vacuum is further provided in the cavity.

Alternatively, after the liquid supply pipe is sealed with the cover, besides the heat transfer liquid, the cavity is further filled with an inert gas.

Alternatively, the liquid supply pipe is made of titanium.

Alternatively, the heat transfer liquid includes heat transfer oil.

Alternative, the crucible is of a cuboid shape.

In another aspect, the present disclosure provides in some embodiments an evaporation device including the above-mentioned crucible.

Alternatively, an external wall and an internal wall of the crucible are made of titanium.

Alternatively, a liquid supply pipe for supplying a heat transfer liquid into a cavity is arranged at a side wall of the external wall, and the liquid supply pipe is made of titanium.

Alternatively, an inlet of the liquid supply pipe is located at a level higher than the side wall.

Alternatively, the liquid supply pipe is provided with a cooling member for cooling the liquid supply pipe, so as to enable a gaseous heat transfer material evaporated and entering the liquid supply pipe to be cooled and converted into the heat transfer liquid, and flow back into the cavity.

Alternatively, the liquid supply pipe is provided with a temperature controller for monitoring a temperature of the liquid supply pipe in real time and transmitting the temperature to the cooling member, so as to enable the cooling member to cool the liquid supply pipe in accordance with a difference between the temperature and a temperature threshold.

Alternatively, a cover for sealing the liquid supply pipe is provided at the inlet of the liquid supply pipe, and after the liquid supply pipe is sealed with the cover, besides the heat transfer liquid, a vacuum or an inert gas is further provided in the cavity.

Alternatively, the heat transfer liquid includes heat transfer oil, and the crucible is of a cuboid shape.

According to the crucible and the evaporation device in the embodiments of the present disclosure, the heat transfer oil is filled between the external wall and the internal wall of the crucible, and when the heat transfer oil is heated by a heating wire, the heat may be rapidly and uniformly transferred to the internal wall of the crucible. After a to-be-evaporated material is added into the crucible, it may be heated uniformly and then evaporated, and meanwhile the to-be-evaporated material may be maintained at a uniform temperature. As a result, it is able to uniformly heat the to-be-evaporated material, thereby to provide a resultant film with a uniform thickness and prevent the to-be-evaporated material to be modified.

### BRIEF DESCRIPTION OF THE DRAWINGS

FIG. 1 is a side view of a crucible;

FIG. 2 is a side view of a crucible according to one embodiment of the present disclosure; and

FIG. 3 is a top view of the crucible according to one embodiment of the present disclosure.

### DETAILED DESCRIPTION OF THE EMBODIMENTS

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

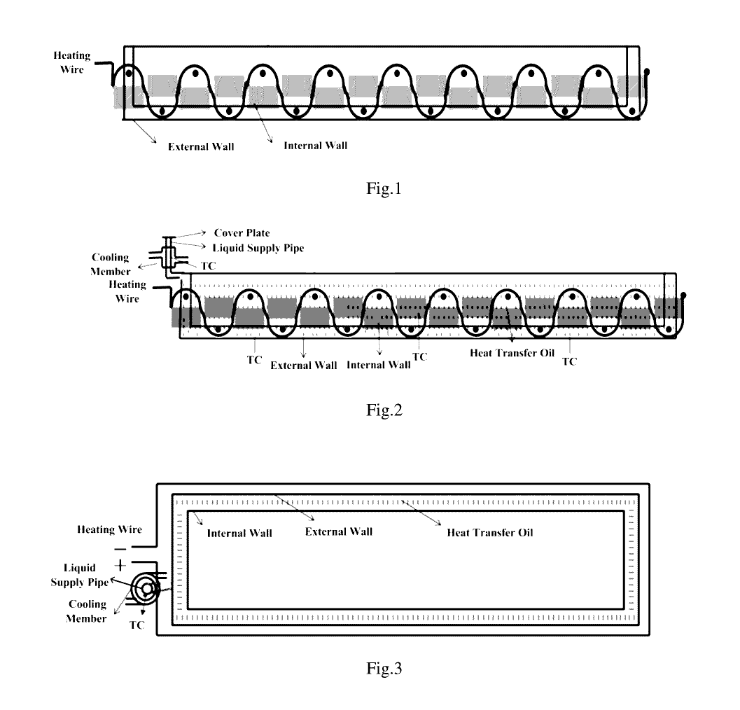

Referring to FIG. 1, which is a side view of a crucible, the crucible is of a hollow structure, and it is heated by an external heating wire. Because the heating wire is easily deformed, a to-be-evaporated material in the crucible may be heated at different temperatures, and a resultant film may be of different thicknesses. In addition, the to-be-evaporated material may be easily modified.

The present disclosure provides in some embodiments a crucible which is still heated by a heating wire. As compared with the above crucible, a heat transfer liquid (e.g., heat transfer oil) is filled between an external wall and an internal wall of the crucible. The crucible may be a linear crucible, i.e., a crucible of a cuboid shape, so as to improve a better heating effect. Due to the heat transfer oil, the crucible may be heated uniformly. As a result, it is able to evaporate a to-be-evaporated material uniformly, provide a resultant film with a uniform thickness and prevent the to-be-evaporated material from being modified.

The crucible will be described hereinafter in conjunction with FIGS. 2 and 3. For ease of description, each member or structure will not be described independently.

The crucible in some embodiments of the present disclosure may include an external wall, an internal wall and a heating member arranged outside the external wall. The external wall and the internal wall define a cavity, and a heat transfer liquid is received in the cavity. Alternatively, the heating member is a heating wire.

For a conventional crucible, a cavity defined by an external wall and an internal wall is filled with gas, and the heating wire is arranged at an outer surface of the external wall of the crucible. Even when the heating wire is arranged evenly in a zigzag manner, a temperature of the crucible at a position adjacent to the heating wire is still higher than that at a position away from the heating wire. In this regard, the external wall of the crucible may be heated non-uniformly. In addition, the gas in the cavity is of relatively low heat-transfer ability, so the internal wall of the crucible may also be heated non-uniformly.

In addition, during the heating, the heating wire may be easily deformed. With the elapse of time, the heating wire may be deformed more seriously, and the temperature difference between the respective portions of the crucible may become larger, so the evaporation of the to-be-evaporated material will be adversely affected. Moreover, when the to-be-evaporated material in the crucible (also called as evaporation groove) does not have excellent thermostability and some portions of the crucible are heated at an excessively high temperature, the to-be-evaporated material may be easily modified.

In the embodiments of the present disclosure, the heat transfer liquid having excellent heat transfer ability is filled within the cavity defined by the external wall and the internal wall, so as to heat the crucible uniformly. During the actual application, various heat transfer liquids may be adopted, and they are not particularly defined herein.

In the related art, the internal wall of the crucible for evaporation is usually made of Cu. However, the stability of Cu, e.g., its resistance to oxidation and to acid or alkali, is insufficient, so the to-be-evaporated material will be adversely affected. In the embodiments of the present disclosure, through experiments, the external wall and the internal wall, i.e., the entire crucible, may be made of titanium (Ti).

To be specific, Ti is of relatively large hardness, so the crucible may not be deformed at a high temperature. In addition, Ti exhibits a large affinity to oxygen, so it is of excellent corrosion resistance. A dense oxide film may be formed on a surface thereof, so as to prevent it from being corroded by a medium. Moreover, Ti exhibits excellent stability in an acidic, alkaline or neutral solution, or in an oxidation medium, so its corrosion resistance is better than stainless steel or any other non-ferrous metal.

The cavity defined by the external wall and the internal wall is used for receiving the heat transfer liquid. The heat transfer liquid may be supplied into the cavity in various ways. For example, (1) the heat transfer liquid may be supplied into the cavity during the manufacture of the crucible, and the cavity may not be provided any opening.

In this case, the crucible is of a relatively short service life, because the heat transfer ability of the heat transfer liquid may be degraded when the property of the heat transfer liquid changes along with the elapse of time. At this time, it is impossible to replace the heat transfer liquid, and instead, the entire crucible shall be replaced, resulting in an increase in the production cost. For another example, (2) an opening may be provided in the external wall of the crucible, so as to facilitate the replacement of the heat transfer liquid when its heat transfer ability has been deteriorated, thereby to reduce the production cost.

Hence, alternatively, a liquid supply pipe (i.e., an oil supply pipe in FIGS. 2 and 3) for supplying the heat transfer liquid into the cavity may be arranged at a side wall of the external wall. It should be appreciated that, the heat transfer liquid in the cavity, the heat transfer ability of which has been deteriorated with the elapse of time, may also be discharged via the liquid supply pipe.

Alternatively, an inlet of the liquid supply pipe may be located at a level higher than the side wall (as shown in FIGS. 2 and 3), so as to supply the heat transfer liquid into the cavity under the effect of gravity.

During the actual application, when the to-be-evaporated material (e.g., an organic material) is heated by the crucible, it is necessary to adjust the temperature of the crucible, so as to prevent the to-be-evaporated material from being modified and improve the evaporation effect. One way is to reduce a temperature of the heat transfer liquid. In addition, when the crucible is heated by the heating wire continuously, the temperature of the heat transfer liquid in the cavity will increase. Although the heat transfer liquid is of a boiling point higher than that of the to-be-evaporated material, a small amount of the heat transfer liquid may be converted into gas, and thereby a pressure inside the cavity may increase. At this time, it is also necessary to reduce the temperature of the heat transfer liquid.

Hence, in order to reduce the temperature of the heat transfer liquid in time and ensure safety, in some embodiments of the present disclosure, the liquid supply pipe may be further provided with a cooling member (i.e., a cooling unit in FIGS. 2 and 3), so as to enable a gaseous heat transfer material evaporated and entering the liquid supply pipe to be cooled and converted into the heat transfer liquid, and flow back into the cavity.

In order to facilitate the control of the temperature of the heat transfer liquid by the cooling member, the liquid supply pipe may be further provided with a temperature controller (TC in FIGS. 2 and 3), so as to monitor a temperature of the liquid supply pipe in real time and transmitting the temperature to the cooling member, thereby to enable the cooling member to cool the liquid supply pipe in accordance with a difference between the temperature and a temperature threshold. The temperature threshold may be preset in accordance with the practical need.

The temperature controller may be provided to monitor the temperature of the liquid supply pipe in real time, thereby to improve a cooling effect of the cooling member. For example, when the temperature of the liquid supply pipe is too high, a cooling gas or liquid in the cooling member may be circulated at a high flow rate.

In an alternative embodiment, a cover may also be provided at the inlet of the liquid supply pipe, so as to seal the liquid supply pipe. When the cavity is filled up with the heat transfer liquid, a predetermined volume of the heat transfer liquid may be discharged from the cavity via the liquid supply pipe in a sealed environment, so as to form a vacuum in the cavity. During the evaporation, usually a space defined by the internal wall of the crucible is not filled up with the to-be-evaporated material, e.g., merely two thirds of the space is filled with the to-be-evaporated material. Hence, a part of the heat transfer liquid may be discharged from the cavity so as to reduce the production cost. Of course, after the formation of the vacuum, the vacuum may also be filled with an inert gas. At this time, the inlet of the liquid supply pipe may be sealed with the cover.

In the embodiments of the present disclosure, the liquid supply pipe may be made of Ti. Of course, it may also be made of any other material, as long as the above-mentioned effect may be achieved.

In an alternative embodiment, the heat transfer liquid may include heat transfer oil. As a heat transfer medium, the heat transfer oil may be heated uniformly at a controlled temperature, and may be heated to a high temperature at a low pressure. As compared with any other heat transfer liquids, the heat transfer oil has better heat transfer ability at lower power consumption, and may be transported and used conveniently. Especially, a novel high-temperature nano heat transfer oil has such advantages as excellent thermostability, rapid heat transfer rate, high operating temperature (up to 500° C., with a boiling point greater than 520° C.) and long service life. Hence, when the heat transfer oil is used, it is able to heat the crucible uniformly and facilitate the adjustment of the temperature of the crucible, thereby to facilitate to adjust an evaporation rate and provide the resultant film with a uniform thickness.

The heat transfer oil may be dibenzyltoluene-containing high-temperature nano heat transfer oil. Alternatively, the heat transfer oil may include 88-99.9 parts by weight of dibenzyltoluene, 0.05-10 parts by weight of modified nano particles, and 0.001-0.5 parts by weight of a flow improver. The nano particles may be metal, metal oxide, non-metal and/or non-metal oxide particles, and a weight ratio of a dispersant to the nano particles is 1:0.05-0.30. As is known in the related art, an operating temperature of the heat transfer oil is up to 500° C., which is larger than a temperature at which the organic material for an OLED element is to be heated (this temperature is less than 350° C., usually 100° C. to 200° C.), so the heat transfer oil may be used in the embodiments of the present disclosure as the heat transfer liquid.

In order to monitor the temperatures at different regions of the external wall of the crucible in real time, as shown in FIG. 2 or 3, a plurality of TCs may also be arranged on the external wall of the crucible. Positions of the TCs maybe set in accordance with the practical need.

The heat transfer oil filled in the cavity between the external wall and the internal wall of the crucible may be used to transfer the heat rapidly, so it is able to heat the internal wall of the crucible uniformly, thereby to heat the to-be-evaporated material in the crucible uniformly. In addition, usually two third or less of the space defined by the internal wall of the crucible is filled with the to-be-evaporated material, so a part of the heat transfer oil may be discharged from the cavity to form a vacuum or the inert gas may be filled into the vacuum. At this time, it is able to ensure safety during the operation.

During the actual application, the liquid supply pipe may be cooled by the cooling member through water, air or the like. To be specific, a flow rate of the water or air, or an initial temperature thereof, may be adjusted so as to cooling the evaporated heat transfer material in the liquid supply pipe at a constant temperature, thereby to flow the resultant heat transfer liquid to be at a temperature approximately identical to the temperature of the heat transfer liquid in the cavity.

In an alternative embodiment, the crucible may be of a cuboid shape, i.e., it may be a linear crucible, so as to improve the evaporation effect.

As compared with the conventional crucible, it is able for the crucible in the embodiments of the present disclosure to be heated uniformly, thereby to heat the to-be-evaporated material uniformly and prevent the to-be-evaporated material from being modified.

The present disclosure further provides in some embodiments of the present disclosure an evaporation device including the above-mentioned crucible.

According to the embodiments of the present disclosure, through the improvement on the crucible in the related art, the heat transfer liquid having excellent heat transfer ability, such as heat transfer oil, is filled between the cavity defined by the external wall and the internal wall of the crucible, so as to transfer the heat rapidly and uniformly. In addition, the external wall and the internal wall are made of Ti, so as to increase the strength of the crucible and prevent the crucible from being deformed at a high temperature. As a result, it is able to heat the crucible uniformly, thereby to heat the to-be-evaporated material in the crucible uniformly and prevent it from being modified.

The above are merely the preferred embodiments of the present disclosure. It should be appreciated that, a person skilled in the art may make further modifications and improvements without departing from the principle of the present disclosure, and these modifications and improvements shall also fall within the scope of the present disclosure.

What is claimed is:

1. A crucible, comprising an external wall, an internal wall and a heating member arranged outside the external wall, wherein the external wall and the internal wall define a cavity, and a heat transfer liquid is received in the cavity.

2. The crucible according to claim 1, wherein the external wall and the internal wall are made of titanium.

3. The crucible according to claim 1, wherein a liquid supply pipe for supplying the heat transfer liquid into the cavity is arranged at a side wall of the external wall.

4. The crucible according to claim 3, wherein an inlet of the liquid supply pipe is located at a level higher than the side wall.

5. The crucible according to claim 4, wherein the liquid supply pipe is provided with a cooling member for cooling the liquid supply pipe, so as to enable a gaseous heat transfer material evaporated and entering the liquid supply pipe to be cooled and converted into the heat transfer liquid, and flow back into the cavity.

6. The crucible according to claim 5, wherein the liquid supply pipe is provided with a temperature controller for monitoring a temperature of the liquid supply pipe in real time and transmitting the temperature to the cooling member, so as to enable the cooling member to cool the liquid supply pipe in accordance with a difference between the temperature and a temperature threshold.

7. The crucible according to claim 3, wherein a cover for sealing the liquid supply pipe is provided at the inlet of the liquid supply pipe.

8. The crucible according to claim 7, wherein after the liquid supply pipe is sealed with the cover, besides the heat transfer liquid, a vacuum is further provided in the cavity.

9. The crucible according to claim 7, wherein after the liquid supply pipe is sealed with the cover, besides the heat transfer liquid, the cavity is further filled with an inert gas.

10. The crucible according to claim 3, wherein the liquid supply pipe is made of titanium.

11. The crucible according to claim 1, wherein the heat transfer liquid comprises heat transfer oil.

12. The crucible according to claim 1, wherein the crucible is of a cuboid shape.

13. An evaporation device, comprising the crucible according to claim 1.

14. The evaporation device according to claim 13, wherein an external wall and an internal wall of the crucible are made of titanium.

15. The evaporation device according to claim 13, wherein a liquid supply pipe for supplying a heat transfer liquid into a cavity is arranged at a side wall of the external wall, and the liquid supply pipe is made of titanium.

16. The evaporation device according to claim 15, wherein an inlet of the liquid supply pipe is located at a level higher than the side wall.

17. The evaporation device according to claim 16, wherein the liquid supply pipe is provided with a cooling member for cooling the liquid supply pipe, so as to enable a gaseous heat transfer material evaporated and entering the liquid supply pipe to be cooled and converted into the heat transfer liquid, and flow back into the cavity.

18. The evaporation device according to claim 17, wherein the liquid supply pipe is provided with a temperature controller for monitoring a temperature of the liquid supply pipe in real time and transmitting the temperature to the cooling member, so as to enable the cooling member to cool the liquid supply pipe in accordance with a difference between the temperature and a temperature threshold.

19. The evaporation device according to claim 15, wherein a cover for sealing the liquid supply pipe is provided at the inlet of the liquid supply pipe, and after the liquid supply pipe is sealed with the cover, besides the heat transfer liquid, a vacuum or an inert gas is further provided in the cavity.

20. The evaporation device according to claim 1, wherein the heat transfer liquid comprises heat transfer oil, and the crucible is of a cuboid shape.
